(19) United States
(12) Patent Application Publication
(10) Pub. No.: US 2010/0123173 A1
(43) Pub. Date: May 20, 2010

(54) Semiconductor device and method of manufacturing the same

(75) Inventor: Masayasu Tanaka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki-shi (JP)

(21) Appl. No.: 12/588,577

(22) Filed: Oct. 20, 2009

(30) Foreign Application Priority Data
Nov. 14, 2008 (JP) 2008-292588

(51) Int. Cl. H01L 29/78; H01L 21/336

(52) U.S. Cl. 257/288; 438/585; 438/151; 257/E29.255; 257/E21.409; 257/E21.214

(57) ABSTRACT

A semiconductor device includes a three-dimensional structure that extends in a channel direction, a stress film having residual stress acting on a first side surface of the three-dimensional structure, a gate insulating film that is formed over a second side surface of the three-dimensional structure, and a gate electrode that covers the three-dimensional structure with the gate insulating film interposed therebetween and extends in a direction in which the first and second side surfaces are opposite to each other. The three-dimensional structure has a channel region between a source electrode and a drain electrode.

This application is based on Japanese patent application No. 2008-292588, the content of which is incorporated hereinto by reference.

### BACKGROUND

1. Technical Field

The present invention relates to a semiconductor device including a field effect transistor (FET) and a method of manufacturing the same, and more particularly, to a semiconductor device including an FET having a metal-insulator-semiconductor (MIS) structure in which crystal distortion occurs in a channel region and a method of manufacturing the same.

2. Related Art

A planar structure is known as a typical structure of the FET having the MIS structure. In the planar structure, a source region, a drain region, and a channel region are arranged substantially on a plane. In recent years, along with advances in element miniaturization, problems have arisen with the planar type structure according to the related art in that mobility is reduced due to an increase in the concentration of impurities, or the amount of junction leakage current is increased due to the decreasing junction depth resulting from a salicide process. In order to solve the above-mentioned problems, some element structures have been proposed, one of which is a fin structure.

An FET having the fin structure (hereinafter, referred to as a “fin-type FET”) has a structure in which a semiconductor substrate is etched into a fin-shaped three-dimensional structure and the side surface of the three-dimensional structure is used as the channel of the MIS-type FET. In recent years, the fin-type FET structure is a general term for an element structure, such as a double gate structure or a tri-gate structure. The double gate structure means a structure in which gate electrodes are formed on two side surfaces of a three-dimensional structure, and the tri-gate structure means a structure in which gate electrodes are formed on two side surfaces and the upper surface of a three-dimensional structure.

As in D. Hisamoto, et al., IEEE Transactions on Electron Devices, Vol. 47, No. 12, pp. 2320-2325 (2000), in the fin-type FET, a channel region is narrowed in order to prevent a short channel effect due to decreasing junction depth. In addition, since the fin-type FET has a structure capable of reducing the impurity concentration of the channel region, it is possible to easily control the carrier mobility and also to prevent an increase in the width of a depletion layer in the semiconductor substrate. Therefore, the fin-type FET has improved subthreshold characteristics. These characteristics make it possible to reduce standby consumption power and to improve switching speed.

In addition, a so-called crystal distortion technique has been proposed which applies distortion from the outside to a crystal substrate forming a channel region to improve carrier mobility, thereby improving the current driving capability of an element. This type of crystal distortion technique is disclosed in, for example, Japanese Unexamined Patent Publication No. 2005-019970 and Japanese Unexamined Patent Publication No. 2007-294757. Japanese Unexamined Patent Publication No. 2005-019970 discloses a technique in which a three-dimensional structure (seed fin) made of a SiC crystal is formed in a p-type fin FET and a three-dimensional structure (seed fin) made of a SiGe crystal is formed in an n-type fin FET. In the disclosed technology, a Si crystal is epitaxially grown on the surface of the seed fin to form a channel region, and compression and tensile crystal distortions are applied to the silicon crystal of the channel region, thereby improving the performance. Japanese Unexamined Patent Publication No. 2007-294757 discloses a technique in which distortion is applied to the silicon crystal of the channel region using a gate electrode.

However, the structure according to the related art is not appropriate in that the crystal distortion technique is applied to a complementary metal oxide semiconductor (CMOS). In order to manufacture the CMOS, it is necessary to integrate at least the n-type and p-type fin FETs. In the n-type fin FET, the carriers that allow a current to flow from the source electrode to the drain electrode are electrons. In the p-type fin FET, the carriers are holes.

When crystal distortion is applied to the silicon crystal by the crystal distortion technique, the directions of the crystal distortion for improving the mobility of the electrons and the holes, which are carriers, are different from each other. For example, in the channel plane, stress is applied to the electrons in one axial direction of the tensile strain, and stress is applied to the holes in two axial directions of the compression strain, thereby improving the mobility of the electrons and the holes. Alternatively, it is necessary to apply the stress of the tensile strain or the compression strain to at least one axial direction in which a current flows. Therefore, in order to obtain the sufficient CMOS performance, it is necessary to integrate different crystal distortions on the same substrate.

In the technique disclosed in Japanese Unexamined Patent Publication No. 2005-019970, in order to manufacture the CMOS, the SiC crystal and the SiGe crystal are formed on the same substrate. However, since there is a large mismatch between the crystal lattices of the SiC crystal and the SiGe crystal, it is difficult to grow the SiC crystal and the SiGe crystal on the same substrate to manufacture a high-performance CMOS, even when, for example, an epitaxial technique is used.

In the technique disclosed in Japanese Unexamined Patent Publication No. 2007-294757, in order to manufacture the CMOS, it is necessary to form two types of gate electrodes with different distortions in the n-type MIS FET and the p-type MIS FET. In addition, it is necessary to perform a manufacturing process twice in order to form the gate electrodes. However, when one of the two gate electrodes is formed by the first manufacturing process, a region of the semiconductor substrate in which the other gate electrode will be formed by the second manufacturing process is likely to suffer etching damage when the first manufacturing process is performed. Therefore, there is a concern that the reliability of the gate insulating film will be lowered. In addition, the manufacturing process becomes complicated.

### SUMMARY

In one embodiment, there is provided a semiconductor device including: a substrate; a three-dimensional structure that is formed over a main surface of the substrate, includes first and second side surfaces opposite to each other in a direction intersecting a channel direction which is parallel to the in-plane direction of the substrate, and extends in the channel direction; a stress film that is formed over the first side surface and includes a residual stress acting on the first side surface; a gate insulating film that is formed over the second side surface; and a gate electrode that covers at least the second side surface of the three-dimensional structure with the gate insulating film interposed between the three dimensional structure and the gate electrode and extends in a direction in which the first and second side surfaces are opposite to each other. The three-dimensional structure includes a source electrode and a drain electrode on both sides of the gate electrode in the channel direction and includes a channel region between the source electrode and the drain electrode.

In another embodiment, there is provided a method of manufacturing a semiconductor device (first manufacturing method) including: etching a semiconductor layer formed over a substrate to form a step structure including a first side surface; forming a patterned stress film over an upper surface and the first side surface of the step structure; performing etching on the step structure using the stress film as an etching mask to form a second side surface opposite to the first side surface, thereby forming a three-dimensional structure that includes first and second side surfaces and extends in a channel direction parallel to the in-plane direction of the substrate; forming a gate insulating film over the second side surface; and forming a gate electrode that covers at least the second side surface of the three-dimensional structure with the gate insulating film interposed between the three-dimensional structure and the gate electrode and extends in a direction in which the first and second side surfaces are opposite to each other. The stress film includes residual stress acting on the first side surface. The three-dimensional structure includes a source electrode and a drain electrode on both sides of the gate electrode in the channel direction and includes a channel region between the source electrode and the drain electrode.

In still another embodiment, there is provided a method of manufacturing a semiconductor device (second manufacturing method) including: forming a patterned mask layer over a semiconductor layer formed over a substrate; performing etching on the semiconductor layer using the mask layer as an etching mask to form a step structure having a first side surface; forming a stress film over the first side surface; forming a patterned resist film so as to cover the first side surface; performing etching on a laminate of the step structure and the mask layer using the resist film as an etching mask to form a second side surface opposite to the first side surface, thereby forming a three-dimensional structure that includes first and second side surfaces and extends in a channel direction parallel to the in-plane direction of the substrate; forming a gate insulating film over the second side surface; and forming a gate electrode that covers at least the second side surface of the three-dimensional structure with the gate insulating film interposed between the three-dimensional structure and the gate electrode and extends in a direction in which the first and second side surfaces are opposite to each other. The stress film includes residual stress acting on the first side surface. The three-dimensional structure includes a source electrode and a drain electrode on both sides of the gate electrode in the channel direction and includes a channel region between the source electrode and the drain electrode.

As described above, the semiconductor device according to the above-mentioned embodiment of the invention includes the stress film having the residual stress acting on the first side surface of the three-dimensional structure having the channel region, and the gate electrode that is formed on the second side surface opposite to the first side surface of the three-dimensional structure with the gate insulating film interposed therebetween. In this way, since crystal distortion occurs in the channel region, it is possible to improve the carrier mobility in the channel region. In addition, it is possible to easily apply crystal distortion to the channel region having the MIS structure, regardless of the n-type FET and the p-type FET. Therefore, it is possible to manufacture a MIS structure with high current driving capability and thus manufacture a CMOS structure with high current driving capability.

In the first method of manufacturing the semiconductor device according to the above-mentioned embodiment of the invention, after a patterned stress film is formed on the upper surface and the first side surface of the step structure, etching is performed on the step structure using the stress film as an etching mask to form the second side surface opposite to the first side surface. In this way, a three-dimensional structure is formed which includes the first and second side surfaces and extends in the channel direction. The gate insulating film and the gate electrode are formed on the second side surface of the three-dimensional structure. Therefore, it is possible to form the channel region as a portion of the three-dimensional structure using a self-aligning method and thus accurately position the channel region. As a result, it is possible to manufacture the semiconductor device with a minute structure.

In the second method of manufacturing the semiconductor device according to the above-mentioned embodiment of the invention, after the stress film is formed on the side surface of the step structure, the step structure is etched using a patterned resist film (resist pattern) to form a three-dimensional structure. The gate insulating film and the gate electrode are formed on the other side surface of the three-dimensional structure. Therefore, it is possible to manufacture the semiconductor device with a small number of processes.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are diagrams schematically illustrating a portion of the structure of a semiconductor device according to a first embodiment of the invention;

FIGS. 2A and 2B are diagrams schematically illustrating a portion of a process of manufacturing the semiconductor device according to the first embodiment;

FIGS. 3A and 3B are diagrams schematically illustrating a portion of the process of manufacturing the semiconductor device according to the first embodiment;

FIGS. 4A and 4B are diagrams schematically illustrating a portion of the process of manufacturing the semiconductor device according to the first embodiment;

FIGS. 5A and 5B are diagrams schematically illustrating a portion of the process of manufacturing the semiconductor device according to the first embodiment;

FIGS. 6A and 6B are diagrams schematically illustrating a portion of the process of manufacturing the semiconductor device according to the first embodiment;

FIGS. 7A and 7B are diagrams schematically illustrating a portion of the process of manufacturing the semiconductor device according to the first embodiment;

FIGS. 8A and 8B are diagrams schematically illustrating a portion of the process of manufacturing the semiconductor device according to the first embodiment;

FIGS. 9A and 9B are diagrams schematically illustrating a portion of the process of manufacturing the semiconductor device according to the first embodiment;

FIGS. 10A and 10B are diagrams schematically illustrating a portion of the process of manufacturing the semiconductor device according to the first embodiment;

FIGS. 11A and 11B are diagrams schematically illustrating a portion of the process of manufacturing the semiconductor device according to the first embodiment;

FIGS. 12A and 12B are diagrams schematically illustrating a portion of the process of manufacturing the semiconductor device according to the first embodiment;

FIGS. 13A and 13B are diagrams schematically illustrating a portion of the process of manufacturing the semiconductor device according to the first embodiment;

FIGS. 14A and 14B are diagrams schematically illustrating a portion of the process of manufacturing the semiconductor device according to the first embodiment;

FIGS. 15A and 15B are diagrams schematically illustrating a portion of the structure of a semiconductor device according to a second embodiment of the invention;

FIGS. 16A to 16D are diagrams schematically illustrating a portion of the process of manufacturing the semiconductor device according to the second embodiment;

FIGS. 17A to 17D are diagrams schematically illustrating a portion of the process of manufacturing the semiconductor device according to the second embodiment;

FIGS. 18A and 18B are diagrams schematically illustrating a portion of the structure of a semiconductor device according to a third embodiment of the invention;

FIG. 19 is a diagram schematically illustrating a portion of the process of manufacturing the semiconductor device according to the third embodiment;

FIGS. 20A and 20B are diagrams schematically illustrating a portion of the structure of a semiconductor device according to a fourth embodiment of the invention;

FIG. 21 is a diagram schematically illustrating a portion of the process of manufacturing the semiconductor device according to the fourth embodiment;

FIGS. 22A and 22B are diagrams schematically illustrating a portion of the structure of a semiconductor device according to a fifth embodiment of the invention;

FIGS. 23A and 23B are diagrams schematically illustrating a portion of the structure of a semiconductor device according to a sixth embodiment of the invention;

FIGS. 24A and 24B are diagrams schematically illustrating a portion of the process of manufacturing the semiconductor device according to the sixth embodiment;

FIGS. 25A and 25B are diagrams schematically illustrating a portion of the process of manufacturing the semiconductor device according to the sixth embodiment;

FIGS. 26A and 26B are diagrams schematically illustrating a portion of the process of manufacturing the semiconductor device according to the sixth embodiment;

FIG. 27 is a diagram schematically illustrating a portion of the structure of a semiconductor device according to a seventh embodiment of the invention;

FIGS. 28A to 28C are diagrams schematically illustrating a portion of the process of manufacturing the semiconductor device according to the seventh embodiment;

FIGS. 29A to 29C are diagrams schematically illustrating a portion of the process of manufacturing the semiconductor device according to the seventh embodiment;

FIGS. 30A and 30B are diagrams schematically illustrating a portion of the process of manufacturing the semiconductor device according to the seventh embodiment;

FIGS. 31A and 31B are diagrams schematically illustrating a portion of the process of manufacturing the semiconductor device according to the seventh embodiment; and

FIGS. 32A and 32B are diagrams schematically illustrating a portion of the process of manufacturing the semiconductor device according to the seventh embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, exemplary embodiments of the invention will be described with reference to the accompanying drawings.

### First Embodiment

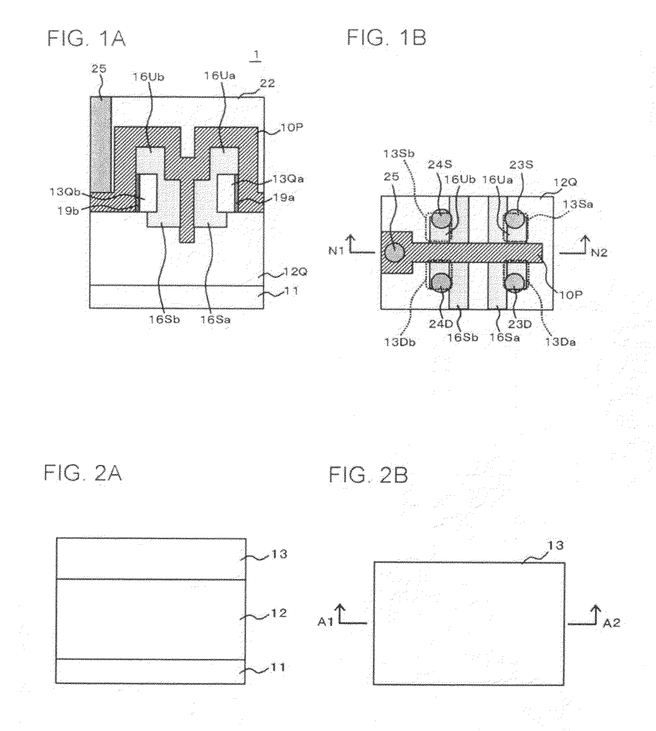

FIG. 1A is a cross-sectional view schematically illustrating a portion of the structure of a semiconductor device 1 according to a first embodiment of the invention, and FIG. 1B is a top view schematically illustrating the main structure of the semiconductor device 1. FIG. 1A is a cross-sectional view illustrating the semiconductor device 1 taken along the line N1-N2 of FIG. 1B. However, for convenience of explanation, an insulating film 22 is not shown in FIG. 1B.

As shown in the cross-sectional view of FIG. 1A, the semiconductor device 1 includes a supporting substrate 11 and channel regions 13Qa and 13Qb that are formed on the main surface of the supporting substrate 11 with an oxide film 12Q interposed therebetween. Each of the channel regions 13Qa and 13Qb has a fin-shaped three-dimensional structure. Each of the three-dimensional structures extends in a channel direction (a direction vertical to the plane of the drawings). The three-dimensional structure forming the channel region 13Qa has two side surfaces that are opposite to each other in a direction which intersects the channel direction (a direction vertical to the plane of the drawings) parallel to the in-plane direction of the supporting substrate 11. A stress film 16Sa is formed on one of the two side surfaces, and a gate oxide film 19a is formed on the other side surface. Similarly, the three-dimensional structure forming the channel region 13Qb has two side surfaces that are opposite to each other in a direction which intersects the channel direction (a direction vertical to the plane of the drawings) parallel to the in-plane direction of the supporting substrate 11. A stress film 16Sb is formed on one of the two side surfaces, and a gate oxide film 19b is formed on the other side surface. In addition, stress films 16Ua and 16Ub are formed on the upper surfaces of the channel regions 13Qa and 13Qb, respectively.

Each of the stress films 16Sa and 16Sb has residual stress acting on the side surface of the three-dimensional structure. Similar to the stress films 16Sa and 16Sb, each of the stress films 16Ua and 16Ub has residual stress acting on the upper surface of the three-dimensional structure. The residual stresses of the stress films 16Sa, 16Sb, 16Ua, and 16Ub cause tensile strain or compression strain to be applied to the surfaces of the three-dimensional structures in the in-plane direction of the surfaces, thereby generating crystal distortion in the channel regions 13Qa and 13Qb. The crystal distortion makes it possible to improve the carrier mobility in the channel regions 13Qa and 13Qb. When an n-type FET semiconductor device 1 is formed, the stress films 16Sa, 16Sb, 16Ua, and 16Ub are formed such that the tensile strain is generated from the surface of the three-dimensional structure. When a p-type FET semiconductor device 1 is formed, the stress films 16Sa, 16Sb, 16Ua, and 16Ub are formed such that the compression strain is generated from the surface of the three-dimensional structure.

As shown in FIGS. 1A and 1B, a gate electrode 10P is continuously formed so as to extend in a direction in which both side surfaces of the three-dimensional structure are opposite to each other. As shown in FIG. 1A, the gate electrode 10P covers the channel region 13Qa with the gate oxide film 19a interposed therebetween and covers the channel region 13Qb with the gate oxide film 19b interposed therebetween.

As shown in FIG. 1A, the channel regions 13Qa and 13Qb are formed below the gate electrode 10P. As shown in FIG. 1B, source electrodes 13Sa and 13Sb are formed on one side of the gate electrode 10P in the channel direction, and drain electrodes 13Da and 13Db are formed on the other side of the gate electrode 10P in the channel direction. The channel region 13Qa, the source electrode 13Sa, and the drain electrode 13Da form one three-dimensional structure, and the channel region 13Qb, the source electrode 13Sb, and the drain electrode 13Db form the other three-dimensional structure.

As shown in FIG. 1B, the stress film 16Ua extends to the upper surface of one three-dimensional structure forming the source electrode 13Sa and the drain electrode 13Da, and the stress film 16Ub extends to the upper surface of the other three-dimensional structure forming the source electrode 13Sb and the drain electrode 13Db. In addition, the stress film 16Sa extends to the side surface of one three-dimensional structure forming the source electrode 13Sa and the drain electrode 13Da, and the stress film 16Sb extends to the side surface of the other three-dimensional structure forming the source electrode 13Sb and the drain electrode 13Db. Therefore, the stress films 16Ua and 16Sa are formed in the entire region in which the carriers can be moved such that crystal distortion occurs in one three-dimensional structure, and the stress films 16Ub and 16Sb are formed in the entire region in which the carriers can be moved such that crystal distortion occurs in the other three-dimensional structure.

For example, silicon nitride films or silicon oxide films may be used as the stress films 16Sa, 16Ua, 16Sb, and 16Ub. It is possible to change deposition conditions to control the residual stresses of the stress films 16Sa, 16Ua, 16Sb, and 16Ub. As the stress film that applies the tensile strain to the three-dimensional structure of a silicon crystal, for example, the following may be used: a silicon nitride film that is formed in a mixed gas atmosphere of a silane gas and an ammonia gas in the temperature range of 700° C. to 800° C. by a low-pressure chemical vapor deposition method (LPCVD method). As the stress film that applies the compression strain to the three-dimensional structure, for example, the following may be used: a silicon oxide film formed by a thermal oxidation method; a silicon oxide film that is formed in a mixed gas atmosphere of a disilane gas and a dinitrogen monoxide gas in the temperature range of 850° C. to 900° C. by the LPCVD method; or a silicon nitride film that is formed at a temperature of, for example, 600° C. or less by a plasma-enhanced chemical vapor deposition method (PECVD method) or an atomic layer deposition method (ALD method) and includes 15 at % or more of hydrogen, preferably, 20 at % to 25 at % of hydrogen.

Then, the insulating film 22 that covers the element structure is formed. A contact plug 25 is provided in a through hole formed in the insulating film 22 so as to reach the gate electrode 10P. In addition, as shown in FIG. 1B, a contact plug 23S connected to the source electrode 13Sa, a contact plug 23D connected to the drain electrode 13Da, a contact plug 24S connected to the source electrode 13Sb, and a contact plug 24D connected to the drain electrode 13Db are provided in the insulating film 22.

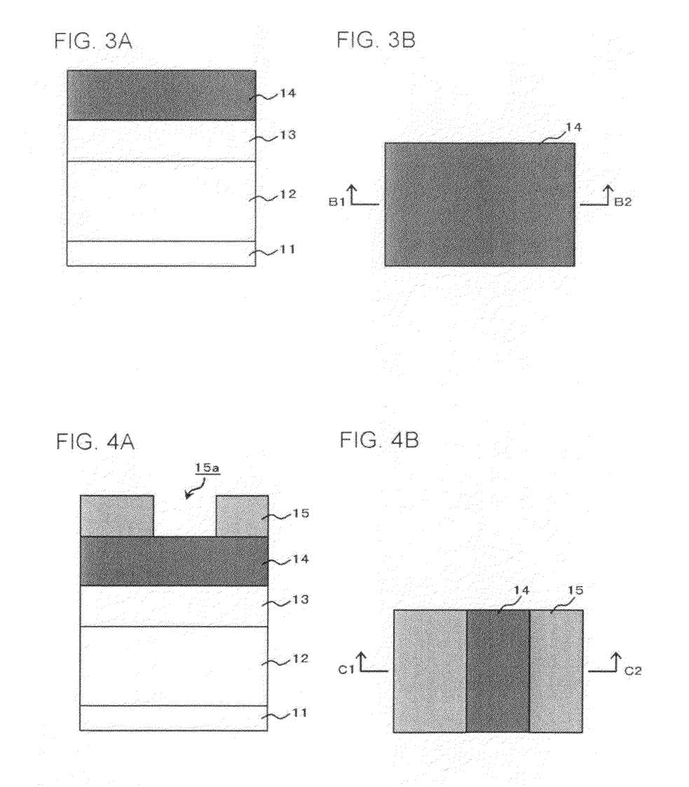

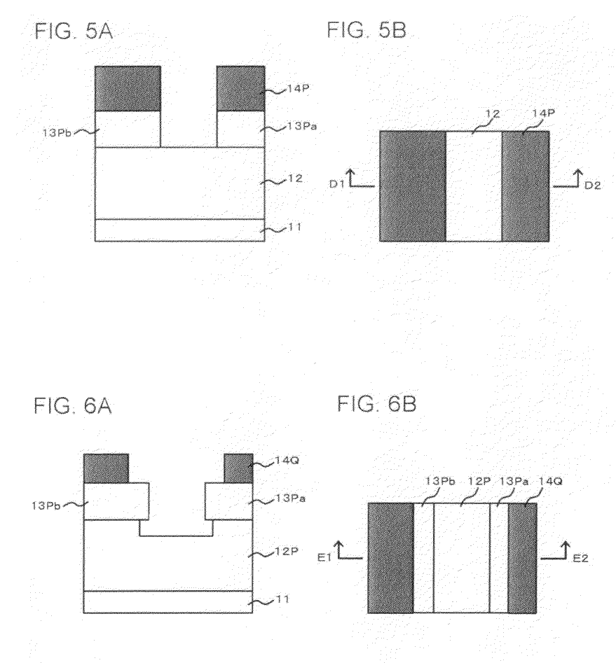

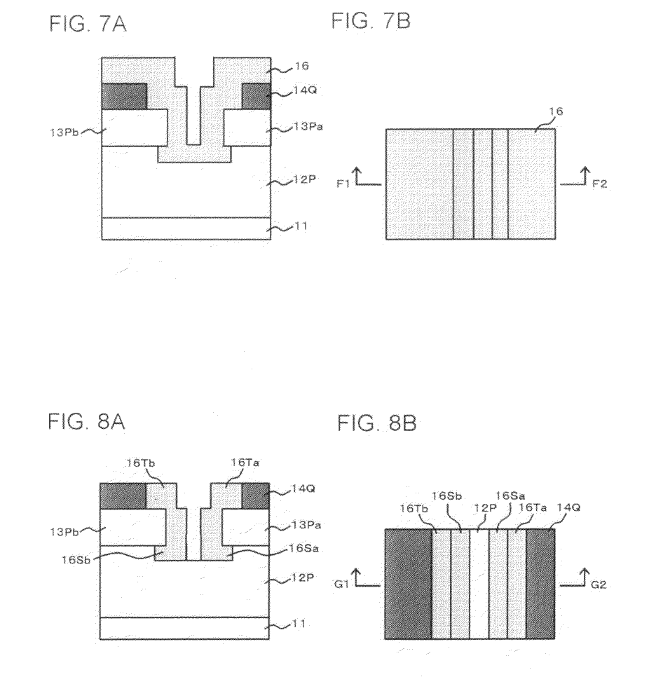

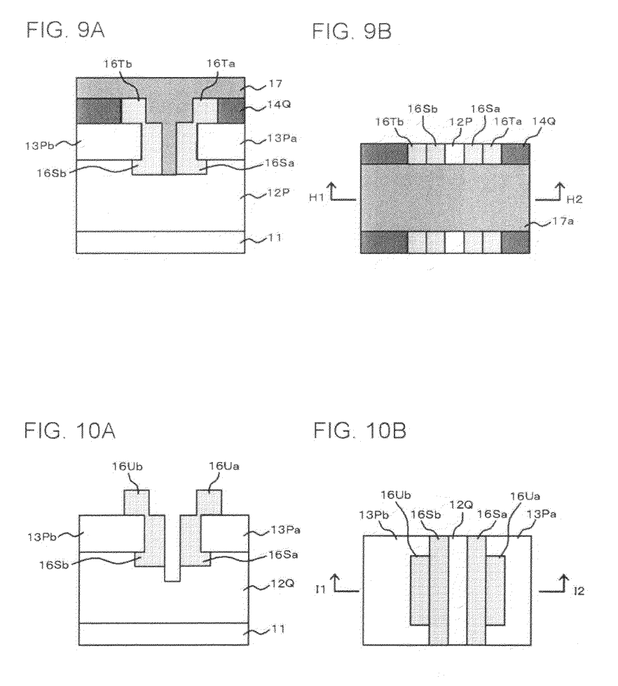

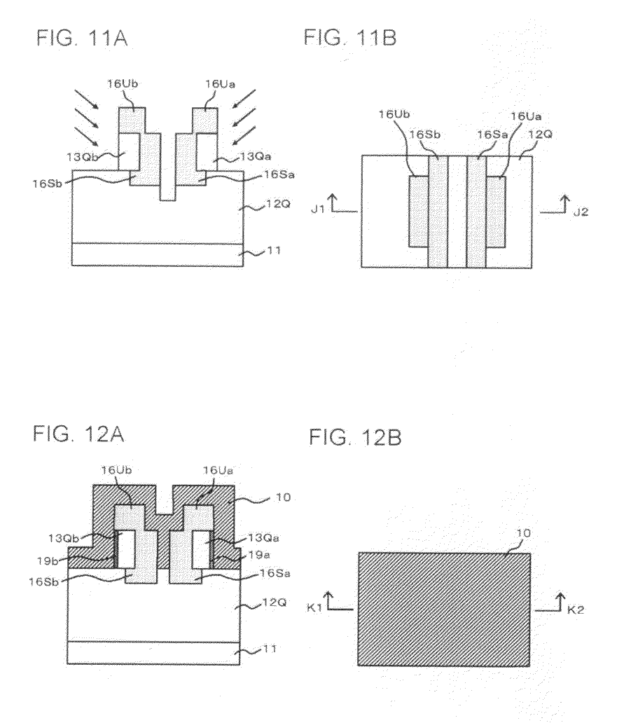

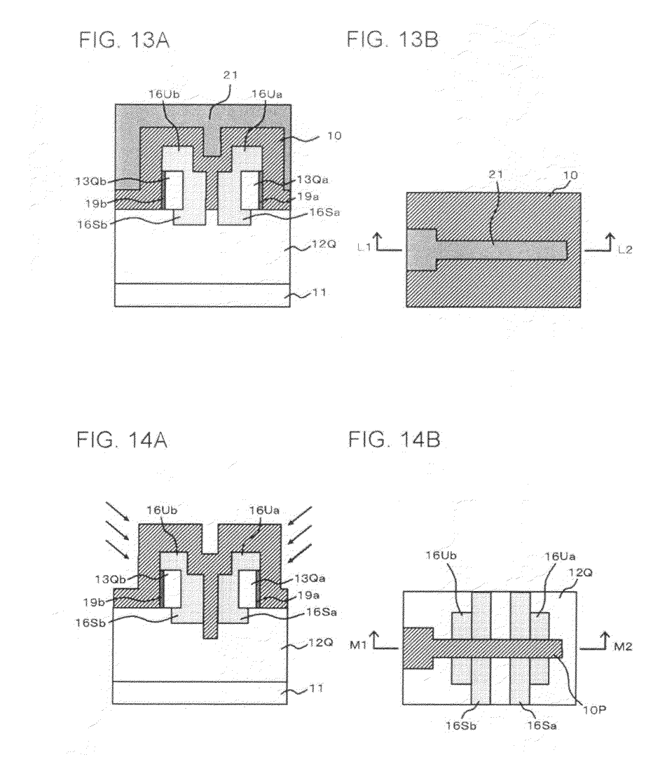

Next, a preferred method of manufacturing the semiconductor device 1 having the above-mentioned structure will be described. FIGS. 2A to 14B are diagrams schematically illustrating processes of manufacturing the semiconductor device 1 having the silicon nitride films formed by the LPCVD method as the stress films 16Sa, 16Ua, 16Sb, and 16Ub shown in FIG. 1A. The stress films 16Sa, 16Ua, 16Sb, and 16Ub have the residual stresses that cause the tensile strain to be applied the channel regions 13Qa and 13Qb. In the manufacturing processes, it is assumed that an n-type FET is manufactured. FIG. 2A is a cross-sectional view illustrating the structure shown in the top view of FIG. 2B taken along the line A1-A2. FIG. 3A is a cross-sectional view illustrating the structure shown in the top view of FIG. 3B taken along the line B1-B2. FIG. 4A is a cross-sectional view illustrating the structure shown in the top view of FIG. 4B taken along the line C1-C2. FIG. 5A is a cross-sectional view illustrating the structure shown in the top view of FIG. 5B taken along the line D1-D2. FIG. 6A is a cross-sectional view illustrating the structure shown in the top view of FIG. 6B taken along the line E1-E2. FIG. 7A is a cross-sectional view illustrating the structure shown in the top view of FIG. 7B taken along the line F1-F2. FIG. 8A is a cross-sectional view illustrating the structure shown in the top view of FIG. 8B taken along the line G1-G2. FIG. 9A is a cross-sectional view illustrating the structure shown in the top view of FIG. 9B taken along the line H1-H2. FIG. 10A is a cross-sectional view illustrating the structure shown in the top view of FIG. 10B taken along the line 11-12. FIG. 11A is a cross-sectional view illustrating the structure shown in the top view of FIG. 11B taken along the line J1-J2. FIG. 12A is a cross-sectional view illustrating the structure shown in the top view of FIG. 12B taken along the line K1-K2. FIG. 13A is a cross-sectional view illustrating the structure shown in the top view of FIG. 13B taken along the line L1-L2. FIG. 14A is a cross-sectional view illustrating the structure shown in the top view of FIG. 14B taken along the line M1-M2.

First, as shown in the cross-sectional view of FIG. 2A, a silicon on insulator (SOI) substrate having a supporting substrate 11 made of a semiconductor material, a buried-oxide film (BOX film) 12, and an SOI layer 13 formed thereon is prepared.

Then, as shown in the cross-sectional view of FIG. 3A, a mask layer 14, which is a silicon oxide film, is formed on the SOI layer 13 by the LPCVD method. The thickness of the BOX film 12 may be, for example, 500 nm, the thickness of the SOI layer 13 may be, for example, 200 nm, and the thickness of the mask layer 14 may be, for example, 100 nm.

Then, a resist film is coated on the SOI layer 13, and a region between the three-dimensional structures (fins) in the resist film is processed by a lithography technique. As a result, as shown in FIG. 4A, a patterned resist film 15 having an opening 15a provided therein is formed. Then, dry etching is performed on the mask layer 14 and the SOI layer 13 using the resist film 15 as an etching mask to process the mask layer 14 and the SOI layer 13, thereby forming a groove. Then, the resist film 15 is removed. As a result, silicon layers 13Pa and 13Pb and the mask layer 14P having two step structures shown in FIG. 5A are formed. The width of the groove is adjusted to, for example, about 150 nm.

Then, the mask layer 14P shown in FIGS. 5A and 5B is selectively etched by, for example, 20 nm with a diluted hydrofluoric acid (DHF) to expose a portion of each of the silicon layers 13Pa and 13Pb in the vicinity of the side wall of the groove (FIGS. 6A and 6B). The width of the exposed portion of the surface (the width in the horizontal direction) is 20 nm, which is substantially equal to the etched amount of the mask layer 14P with the DHF. Simultaneously, the BOX film 12 is also etched to form a silicon layer 12P having a concave portion shown in FIG. 6A. However, since the thickness of the BOX film 12 is sufficiently large, the supporting substrate 11 is not exposed by etching.

Then, a stress film 16 is conformally deposited on the element shown in FIGS. 6A and 6B by the LPCVD technique (FIGS. 7A and 7B). The thickness of the stress film 16 is larger than 20 nm, which is the etched amount of the mask layer 14P with the DHF. For example, the thickness of the stress film 16 may be adjusted to about 50 nm. A silicon nitride film formed at a high temperature may be used as the stress film 16 such that tensile stress is applied to the channel region. The reason why the thickness of the stress film 16 is larger than 20 nm, which is the etched amount of the mask layer 14P shown in FIGS. 5A and 5B, is to prevent the upper surface of the three-dimensional structure (fin) from being exposed due to the recession of the stress film when etching is performed in the subsequent manufacturing process (FIG. 11A) using the stress film as an etching mask.

Then, the stress film 16 is etched in the vertical direction by a dry etching technique such that the stress film 16Sa remains on the side surfaces of the silicon layer 13Pa and the mask layer 14Q and the stress films 16Ta and 16Tb remain on the exposed upper surfaces of the silicon layers 13Pa and 13Pb (FIGS. 8A and 8B).

Then, a resist film for element isolation is coated on the structure shown in FIG. 8A, and the resist film in an element region is patterned by a lithography technique. As a result, as shown in FIGS. 9A and 9B, a patterned resist film 17 is formed. Then, the stress film 16 on the silicon layers 13Pa and 13Pb outside the element region is etched to expose a portion of the upper surface of each of the silicon layers 13Pa and 13Pb, and the resist film 17 peels off. In the etching process, outside the element region, the stress films 16Sa and 16Sb formed on the side surfaces of the silicon layers 13Pa and 13Pb are partially etched. However, in the element region, the stress films are not affected by the etching process. Then, a mask layer 14Q, which is a silicon oxide film, is selectively etched with a DHF solution, thereby obtaining the structure shown in FIGS. 10A and 10B. During the etching process, a portion of the oxide film 12P is etched to obtain an oxide film 12Q having a concave portion shown in FIG. 10A formed therein. However, since the oxide film 12P is thick, the supporting substrate 11 is not exposed.

Then, dry etching is performed on the silicon layers 13Pa and 13Pb using the stress films 16Ua and 16Ub as an etching mask to form three-dimensional structures (fins) having channel regions (fin channels) 13Qa and 13Qb shown in FIG. 11A. The width of the fin is about 20 nm. A biaxial tensile stress is generated in the channel region 13Qa by the side stress film 16Sa and the upper stress film 16Ua. Similarly, a biaxial tensile stress is generated in the channel region 13Qb by the side stress film 16Sb and the upper stress film 16Ub. These tensile stresses make it possible to improve the carrier mobility (electrons).

Then, if necessary, a group-III element, such as boron, is implanted into the channel regions 13Qa and 13Qb by an ion implantation technique and is then activated by a heat treatment.

Then, as shown in FIG. 12A, gate oxide films 19a and 19b are formed on the surfaces of the channel regions 13Qa and 13Qb, respectively, and an electrode layer 10 is formed on the entire surface of the element. For example, silicon oxynitride films formed by a thermal oxidation method and a plasma nitridation method may be used as the gate oxide films 19a and 19b. For example, a polycrystalline silicon film formed by the LPCVD method is used as the electrode layer 10.

Then, a resist film is deposited on the structure shown in FIG. 12A, and the resist film is processed by a lithography technique to form the patterned resist film 21 (FIGS. 13A and 13B). Then, dry etching is performed on the electrode layer 10 using the resist film 21 as a mask to form a gate electrode 10P shown in FIGS. 14A and 14B. Then, the resist film 21 is peeled off. Since the channel regions 13Qa and 13Qb are protected by the stress films 16Ua, 16Ub, 16Sa, and 16Sb, which are nitride films, they are not etched.

Then, as shown in FIG. 14A, a group-V element, such as arsenic or phosphorous, is implanted into the regions disposed on both sides of the gate electrode 10P in the channel direction by the ion implantation technique using the gate electrode 10P as a mask, and a heat treatment is performed to activate the impurities, thereby forming the source electrodes 13Sa and 13Sb and the drain electrodes 13Da and 13Db (FIG. 1B).

Then, if necessary, wiring lines for electrical connection to an external circuit are formed. Specifically, an insulating film is deposited on the structure shown in FIG. 14A, and the insulating film is planarized by a CMP technique. Then, a resist film is coated on the insulating film by the lithography technique, and a contact hole pattern is transferred onto the resist film. In addition, the insulating film is etched by the dry etching technique, and the stress films 16Ua and 16Ub (FIG. 14B) on the source electrodes 13Sa and 13Sb and the drain electrodes 13Da and 13Db (FIGS. 1A and 1B) are partially etched to form contact holes. Then, the resist film peels off, and the formed contact holes are filled with a metal material, such as tungsten, thereby forming the contact plugs 23S, 23D, 24S, 24D, and 25 (FIGS. 1A and 1B).

The effects of the semiconductor device 1 and the method of manufacturing the same according to the first embodiment are as follows.

As described above, in the semiconductor device 1, the stress films 16Sa, 16Sb, 16Ua and 16Ub are formed on the side surfaces and the upper surfaces of the three-dimensional structures including the channel regions 13Qa and 13Qb. In this way, crystal distortion occurs in the channel regions 13Qa and 13Qb. Therefore, it is possible to improve the carrier mobility in the channel regions 13Qa and 13Qb. As a result, it is possible to manufacture an FET having high current driving capability.

According to the method of manufacturing the semiconductor device 1, the silicon layers 13Pa and 13Pb forming the step structures are formed (FIGS. 6A and 6B), and the patterned stress films 16Ua, 16Ub, 16Sa, and 16Sb are formed on the upper surfaces and the side surfaces of the step structures (FIGS. 10A and 10B). Then, the step structures are etched using the stress films 16Ua, 16Ub, 16Sa, and 16Sb as an etching mask to form the three-dimensional structures including the channel regions 13Qa and 13Qb (FIGS. 11A and 11B). In this way, it is possible to form the channel regions 13Qa and 13Qb, which are portions of the three-dimensional structures, using a self-aligning method and thus accurately position the channel regions 13Qa and 13Qb. Therefore, it is possible to form a minute fin that exceeds the limitation of masking in the lithography technique. As a result, it is possible to improve a drain current using a crystal distortion technique and manufacture the semiconductor device 1 with a minute structure.

In the manufacturing method according to this embodiment, two fins including the channel regions 13Qa and 13Qb are formed by the same manufacturing process. That is, as shown in FIGS. 11A and 11B, a pair of channel regions 13Qa and 13Qb is formed with the groove interposed therebetween. This formation is referred to as “pair formation” or “isolation formation”. Since the fins are formed by self-alignment, it is possible to reduce the gap between the fins to be smaller than a minimum line interval and a minimum space interval that can be dissected by the lithography technique.

### Second Embodiment

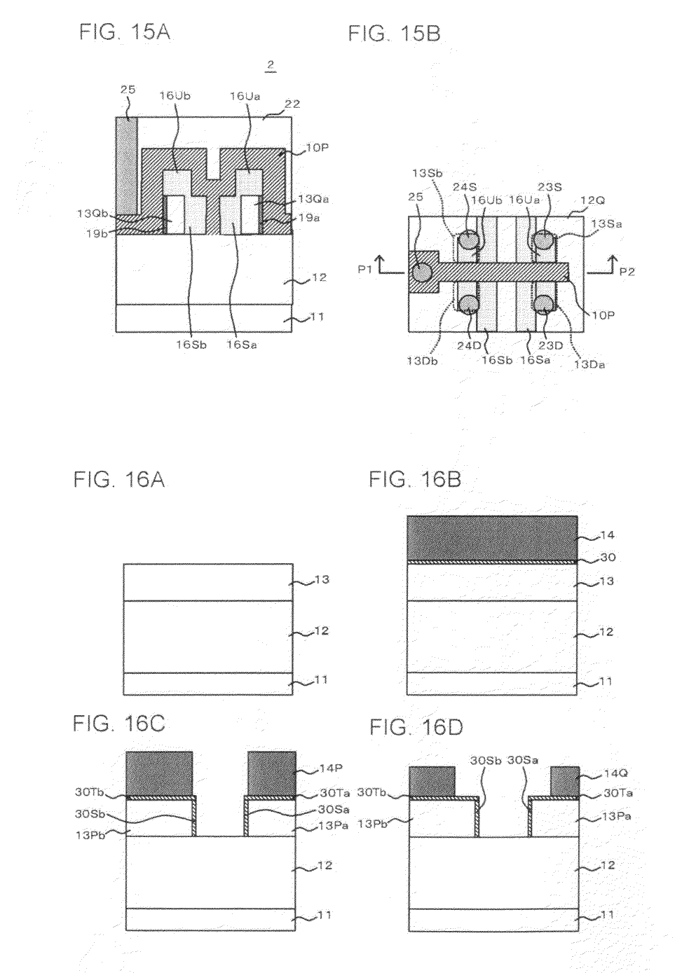

Next, a second embodiment will be described. FIG. 15A is a cross-sectional view schematically illustrating a portion of the structure of a semiconductor device 2 according to the second embodiment, and FIG. 15B is a top view schematically illustrating the main structure of the semiconductor device 2. FIG. 15A is a cross-sectional view illustrating the semiconductor device 2 taken along the line P1-P2 of FIG. 15B.

As shown in FIG. 15A, the semiconductor device 2 has substantially the same structure as the semiconductor device 1 (FIGS. 1A and 1B) according to the first embodiment except that the stress films 16Sa, 16Ua, 16Sb, and 16Ub are silicon oxide films. Since compression stress is applied to the channel regions (fin channels) 13Qa and 13Qb by the influence of the stress films 16Sa, 16Ua, 16Sb, and 16Ub, which are silicon oxide films, the FET structure of the semiconductor device 2 is effective in improving the performance of a p-type FET.

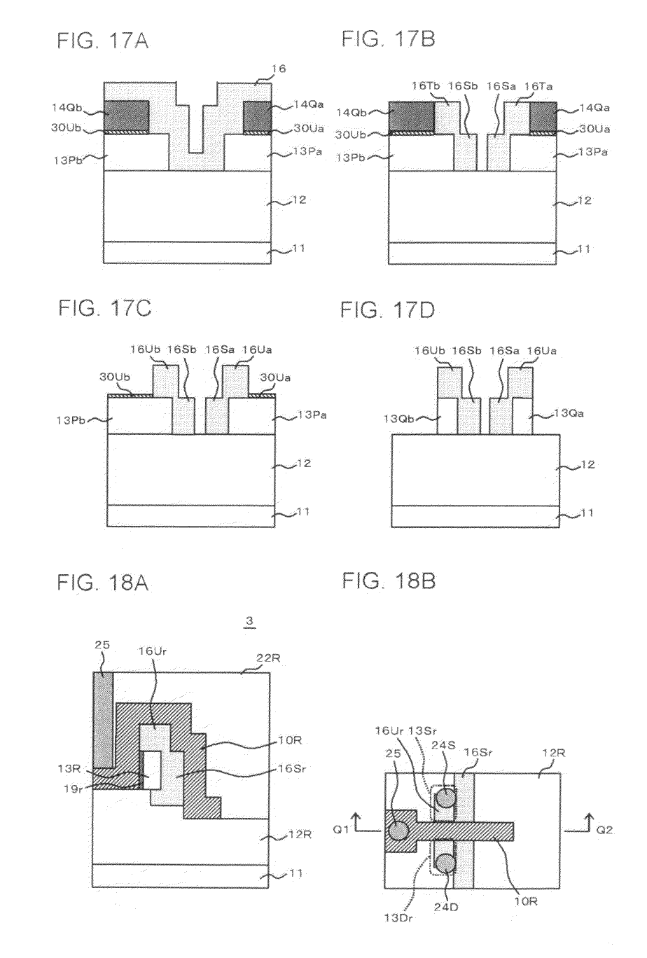

Next, a preferred method of manufacturing the semiconductor device 2 will be described. FIGS. 16A to 16D and FIGS. 17A to 17D are cross-sectional views schematically illustrating a portion of a process of manufacturing the semiconductor device 2 including a p-type FET.

First, as shown in FIG. 16A, an SOI substrate having a supporting substrate 11, a BOX film 12, and an SOI layer 13 formed thereon is prepared.

Then, as shown in FIG. 16B, a thin mask surface oxide film 30, which is a silicon oxide film, and a mask layer 14, which is a silicon nitride film, are sequentially formed on the SOI layer 13. The oxide film 30 may be formed with a thickness of, for example, about 2 nm by the thermal oxidation method, and the mask layer 14 may be formed with a thickness of, for example, about 100 nm by the LPCVD method.

Then, a patterned resist film is formed on the mask layer 14 by the lithography technique through the same manufacturing process as that in the first embodiment (FIGS. 4A and 4B and FIGS. 5A and 5B). Then, dry etching is performed on the mask layer 14, the oxide film 30, and the SOI layer 13 using the resist film as an etching mask to form a groove for forming step structures. Then, the resist film peels off. Then, thermal oxidation is selectively performed on the side wall of the exposed SOI layer 13. As a result, as shown in FIG. 16C, silicon layers 13Pa and 13Pb, oxide films 30Ta, 30Tb, 30Sa, and 30Sb, and a mask layer 14P are formed. The oxide films 30Sa and 30Sb respectively formed on the side surfaces of the silicon layers 13Pa and 13Pb are silicon oxide films with a thickness of about 2 nm.

Then, the mask layer 14P is etched by about 20 nm with a phosphoric acid to expose a portion of the upper surface of each of the oxide films 30Ta and 30Tb in the vicinity of the side wall of the groove. In this case, the etching of the mask layer 14P starts from the side wall of the groove, and the mask layer 14P in the vicinity of the groove is recessed. However, when the phosphoric acid is used, an etching rate for the silicon oxide film is significantly lower than that for a silicon crystal. Therefore, the silicon oxide film serves as a protective film, and the silicon layers 13Pa and 13Pb are not etched with the phosphoric acid. As a result, as shown in FIG.

17A, the oxide films 30Ua and 30Ub respectively covered with the mask layers 14Qa and 14Qb remain.

Then, a stress film 16, which is a silicon oxide film, is conformally deposited by the LPCVD method (FIG. 17A). The thickness of the stress film 16 is greater than the etched amount of the mask layer 14 with the phosphoric acid. For example, the thickness of the stress film 16 is 50 nm.

Then, the stress film 16 is etched by a vertical dry etching technique. As a result, as shown in FIG. 17B, the stress films 16Sa and 16Sb are formed on the side surfaces of the silicon layers 13Pa and 13Pb, respectively, and the stress films 16Ta and 16Tb are formed on the upper surfaces of the silicon layers 13Pa and 13Pb, respectively. Then, the mask layers 14Qa and 14Qb (silicon nitride films) are etched with a phosphoric acid to be removed. In this case, since the silicon layers 13Pa and 13Pb are covered and protected by the oxide films 30Ua and 30Ub, they are not etched by the phosphoric acid.

Then, a patterned resist film is formed in the element region by the lithography technique through the same manufacturing process as that in the first embodiment (FIGS. 9A and 9B, FIGS. 10A and 10B, and FIGS. 11A and 11B), and dry etching is performed on the stress films 16Ta and 16Tb formed on the silicon layers 13Pa and 13Pb using the resist film as an etching mask. As a result, the stress films 16Ua and 16Ub remain only in the element region (FIG. 17C). Then, the resist film peels off.

Then, the mask surface oxide film 30 (silicon oxide film) remaining on the silicon layers 13Pa and 13Pb is etched by about 2 nm by the vertical dry etching technique. Then, vertical dry etching is selectively performed on the mask surface oxide film 30 using the stress films 16Ua and 16Ub (silicon oxide films) on the silicon layers 13Pa and 13Pb as a mask. As a result, as shown in FIG. 17D, the three-dimensional structures (fins) having the channel regions (fin channels) 13Qa and 13Qb are formed. The width of the fin is about 20 nm. A biaxial compression stress is generated in the channel region 13Qa by the side stress film 16Sa and the upper stress film 16Ua. Similarly, a biaxial compression stress is generated in the channel region 13Qb by the side stress film 16Sb and the upper stress film 16Ub. These compression stresses make it possible to improve the carrier mobility (holes).

The subsequent processing processes are the same as those in the first embodiment. That is, if necessary, a group-V element, such as arsenic or phosphorous, is implanted into the channel regions 13Qa and 13Qb by ion implantation, and a heat treatment is performed to activate the impurities. Then, the gate oxide films 19a and 19b and the gate electrode 10P shown in FIG. 15A are formed. Then, a group-III element, such as B or BF2, is implanted into the regions disposed on both sides of the gate electrode 10P in the channel direction by the ion implantation technique using the gate electrode 10P as a mask, and a heat treatment is performed to activate the impurities, thereby forming the source electrodes 13Sa and 13Sb and the drain electrodes 13Da and 13Db (FIG. 15B). Then, an insulating film 22 having the contact plugs 23S, 23D, 24S, 24D, and 25 (FIGS. 15A and 15B) provided therein is formed.

The effects of the semiconductor device 2 according to the second embodiment and a method of manufacturing the same are as follows.

As described above, since the semiconductor device 2 according to this embodiment has substantially the same structure as that according to the first embodiment, it is possible to improve the carrier mobility in the channel regions 13Qa and 13Qb. According to the structure of the semiconductor device 2, since crystal distortion can easily occur in the channel regions 13Qa and 13Qb of the p-type FET, it is possible to easily manufacture a p-type FET with high current driving capability. As the other effect, it is possible to obtain substantially the same effects as those in the semiconductor device 1 according to the first embodiment and the method of manufacturing the same.

### Third and Fourth Embodiments

Next, third and fourth embodiments of the invention will be described. FIG. 18A is a cross-sectional view schematically illustrating a portion of the structure of a semiconductor device 3 according to the third embodiment, and FIG. 18B is a top view schematically illustrating the main structure of the semiconductor device 3. FIG. 18A is a cross-sectional view illustrating the semiconductor device 3 taken along the line Q1-Q2 of FIG. 18B. However, for convenience of explanation, an insulating film 22R is not shown in FIG. 18B.

The semiconductor devices 1 and 2 according to the first and second embodiments each include a pair of fins formed by the same manufacturing process. The fins share one gate electrode 10P. In contrast, the semiconductor device 3 according to the third embodiment includes an isolated fin, and does not share a gate electrode 10R. Similarly, a semiconductor device 4 (FIG. 20A) according to a fourth embodiment, which will be described below, includes an isolated fin.

The structure of the semiconductor device 3 according to the third embodiment is substantially the same as that of the left one of a pair of fins of the semiconductor device 1 according to the first embodiment. That is, the semiconductor device 3 includes a supporting substrate 11 and a channel region 13R that is formed on the main surface of the supporting substrate 11 with an oxide film 12R interposed therebetween. The channel region 13R forms a fin-shaped three-dimensional structure (fin), and the three-dimensional structure extends in the channel direction (a direction vertical to the plane of the drawing). The three-dimensional structure has two side surfaces that are opposite to each other in a direction intersecting the channel direction (a direction vertical to the plane of the drawing). A stress film 16Sr is formed on one of the two side surfaces, and a gate oxide film 19r is formed on the other side surface. In addition, a stress film 16Ur is formed on the upper surface of the channel region 13R.

Each of the stress films 16Sr and 16Ur has residual stress acting on the side surface of the three-dimensional structure. The residual stresses of the stress films 16Sr, and 16Ur cause tensile strain or compression strain to be applied to the surface of the three-dimensional structure in the in-plane direction of the surface, thereby generating crystal distortion in the channel region. When an n-type FET semiconductor device 3 is formed, the stress film 16Sr is formed such that the tensile strain is generated from the surface of the three-dimensional structure. When a p-type FET semiconductor device 3 is formed, the stress film 16Sr is formed such that the compression strain is generated from the surface of the three-dimensional structure.

A method of manufacturing the semiconductor device 3 will be described briefly below.

First, an SOI substrate is prepared similar to the manufacturing process according to the first embodiment (FIGS. 2A and 2B). Then, a mask layer 14, which is a silicon oxide film, is deposited on the SOI layer 13 by the LPCVD method. Then, a resist film is coated on the SOI layer 13, and the resist film is processed by the lithography technique. As a result, a resist film (not shown) with a step difference is formed. Then, dry etching is performed on the mask layer 14 and the SOI layer 13 using the resist film as an etching mask to process the mask layer 14 and the SOI layer 13, thereby forming step structures. Then, the resist film is removed.

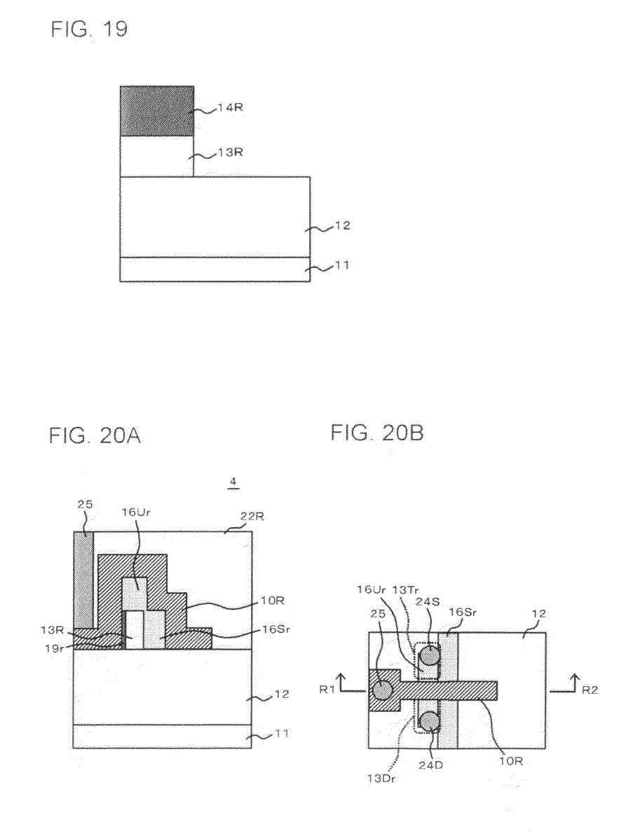

As a result, as shown in FIG. 19, the silicon layer (channel region) 13R and the mask layer 14R having a step difference are formed. The subsequent manufacturing processes are substantially the same as those in the first embodiment (FIGS. 6A to 14B), and thus a description thereof will not be repeated. Finally, an insulating film 22R having contact plugs 24S, 24D, and 25 provided therein is formed to manufacture the semiconductor device 3 shown in FIGS. 18A and 18B.

FIG. 20A is a cross-sectional view schematically illustrating a portion of the structure of the semiconductor device 4 according to the fourth embodiment, and FIG. 20B is a top view schematically illustrating the main structure of the semiconductor device 4. FIG. 20A is a cross-sectional view illustrating the semiconductor device 4 taken along the line R1-R2 of FIG. 20B. However, for convenience of explanation, an insulating film 22R is not shown in FIG. 20B.

The structure of the semiconductor device 4 according to the fourth embodiment is substantially the same as that of the semiconductor device 3 (FIGS. 18A and 18B) according to the third embodiment except that the upper surface of the oxide film 12 is flat, and thus a detailed description of the structure will not be repeated. In addition, the structure of the semiconductor device 4 is substantially the same as that of the left one of a pair of fins of the semiconductor device 2 according to the second embodiment.

A method of manufacturing the semiconductor device 4 will be described briefly below.

First, an SOI substrate is prepared similar to the manufacturing process according to the second embodiment (FIG. 16A). Then, a thin mask surface oxide film 30, which is a silicon oxide film, and a mask layer 14, which is a silicon nitride film, are sequentially formed on the

SOI layer 13 by the same manufacturing process as that shown in FIG. 16B. Then, a resist film is coated on the SOI layer 13, and the resist film is processed by the lithography technique. As a result, a resist film (not shown) with a step difference is formed. Then, dry etching is performed on the mask layer 14, the oxide film 30, and the SOI layer 13 using the resist film as an etching mask to process the mask layer 14, the oxide film 30, and the SOI layer 13, thereby forming a step structure. Then, the resist film is removed. Thereafter, thermal oxidation is selectively performed on the side wall of the exposed SOI layer 13.

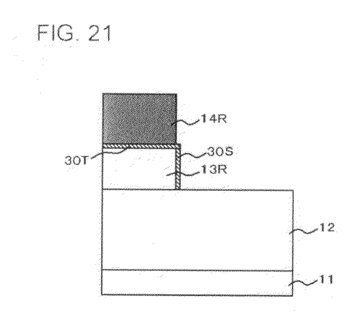

As a result, as shown in FIG. 21, a silicon layer (channel region) 13R and a mask layer 14R having a step difference are formed. An oxide film 30T is formed on the upper surface of the silicon layer 13R, and an oxide film 30S is formed on the side surface of the silicon layer 13R.

The subsequent manufacturing processes are substantially the same as those in the second embodiment (FIGS. 16D to 17D), and thus a detailed description thereof will not be repeated. Finally, an insulating film 22R having the contact plugs 24S, 24D, and 25 provided therein is formed to manufacture the semiconductor device 4 shown in FIGS. 20A and 20B.

The effects of the semiconductor device 3 according to the third embodiment are substantially the same as those of the semiconductor device 1 according to the first embodiment. In addition, the effects of the semiconductor device 4 according to the fourth embodiment are substantially the same as those of the semiconductor device 2 according to the second embodiment.

### Fifth Embodiment

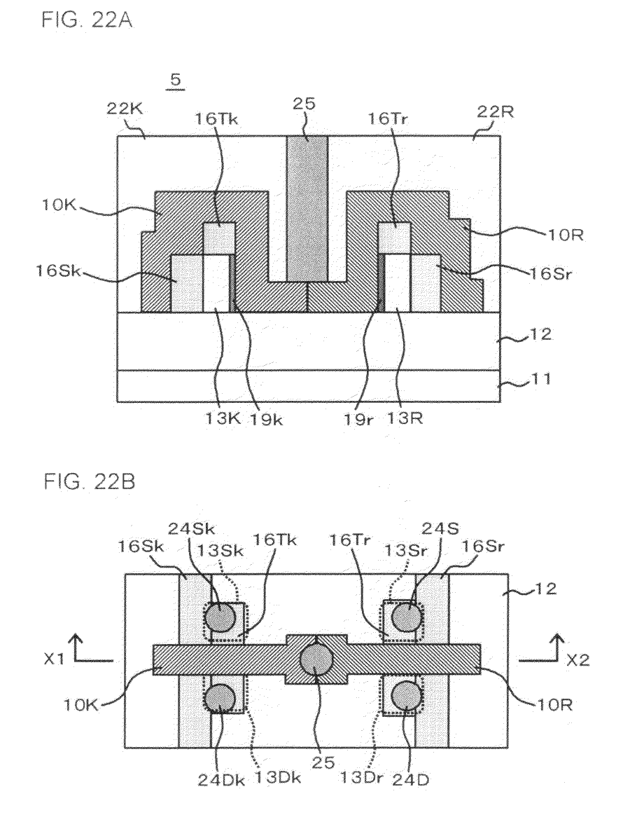

Next, a fifth embodiment of the invention will be described. FIG. 22A is a cross-sectional view schematically illustrating a portion of the structure of a semiconductor device 5 according to the fifth embodiment, and FIG. 22B is a top view schematically illustrating the main structure of the semiconductor device 5. FIG. 22A is a cross-sectional view illustrating the semiconductor device 5 taken along the line X1-X2 of FIG. 22B. However, for convenience of explanation, insulating films 22R and 22K shown in FIG. 22A are not shown in FIG. 22B.

The semiconductor device 5 according to this embodiment is a CMOS semiconductor device in which an n-type FET and a p-type FET are integrated on the same supporting substrate 11.

The n-type FET includes a channel region 13K that is formed on the main surface of the supporting substrate 11 with an oxide film 12 interposed therebetween. The channel region 13K forms a fin-shaped three-dimensional structure (fin), and the three-dimensional structure extends in the channel direction (a direction vertical to the plane of the drawing). The three-dimensional structure has two side surfaces that are opposite to each other in a direction intersecting the channel direction (a direction vertical to the plane of the drawing). A stress film 16Sk is formed on one of the two side surfaces, and a gate oxide film 19k is formed on the other side surface. In addition, a stress film 16Tk is formed on the upper surface of the channel region 13K.

Each of the stress films 16Sk and 16Tk has residual stress acting on the side surface of the three-dimensional structure. The residual stresses of the stress films 16Sk and 16Tk cause tensile strain to be applied to the surface of the three-dimensional structure in the in-plane direction of the surface, thereby generating crystal distortion in the channel region 13K. In this way, it is possible to improve the mobility of electrons, which are carriers.

The p-type FET includes a channel region 13R that is formed on the main surface of the supporting substrate 11 with the oxide film 12 interposed therebetween. The channel region 13R forms a fin-shaped three-dimensional structure (fin), and the three-dimensional structure extends in the channel direction (a direction vertical to the plane of the drawing). The three-dimensional structure has two side surfaces that are opposite to each other in a direction intersecting the channel direction (a direction vertical to the plane of the drawing). A stress film 16Sr is formed on one of the two side surfaces, and a gate oxide film 19r is formed on the other side surface.

In addition, a stress film 16Tr is formed on the upper surface of the channel region 13R.

Each of the stress films 16Sr and 16Tr has residual stress acting on the side surface of the three-dimensional structure. The residual stresses of the stress films 16Sr and 16Tr cause compression strain to be applied to the surface of the three-dimensional structure in the in-plane direction of the surface, thereby generating crystal distortion in the channel region 13R. In this way, it is possible to improve the mobility of holes, which are carriers.

The n-type FET and the p-type FET can be individually manufactured by the manufacturing method according to the third embodiment or the fourth embodiment.

As described above, in the semiconductor device 5 according to this embodiment, the n-type FET and the p-type FET are integrated on the same supporting substrate 11. Therefore, the semiconductor device 5 has a CMOS structure with high current driving capability.

### Sixth Embodiment

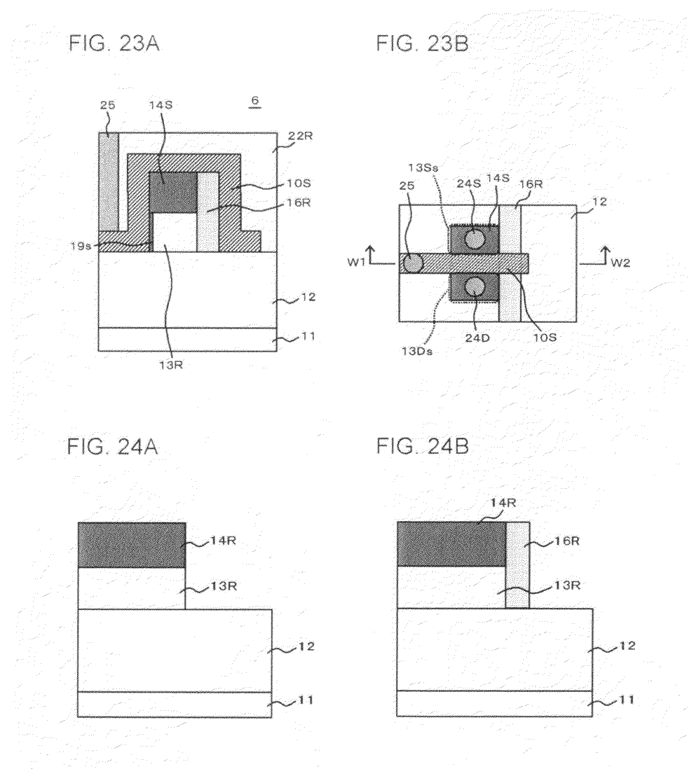

Next, a sixth embodiment of the invention will be described. FIG. 23A is a cross-sectional view schematically illustrating a portion of the structure of a semiconductor device 6 according to the sixth embodiment, and FIG. 23B is a top view schematically illustrating the main structure of the semiconductor device 6. FIG. 23A is a cross-sectional view illustrating the semiconductor device 6 taken along the line W1-W2 of FIG. 23B.

In the semiconductor device 6 according to this embodiment, a channel region (fin channel) is formed by the lithography technique. When the lithography technique is used, it is possible to reduce the number of manufacturing processes, as compared to the fin self-aligning method according to the first to fifth embodiments.

As shown in the cross-sectional view of FIG. 23A, the semiconductor device 6 includes a supporting substrate 11 and a channel region 13R that is formed on the main surface of the supporting substrate 11 with the oxide film 12 interposed therebetween. The channel region 13R forms a fin-shaped three-dimensional structure (fin), and the three-dimensional structure extends in the channel direction (a direction vertical to the plane of the drawing). The three-dimensional structure has two side surfaces that are opposite to each other in a direction which intersects the channel direction (a direction vertical to the plane of the drawings) parallel to the in-plane direction of the supporting substrate 11. A stress film 16R is formed on one of the two side surfaces, and a gate oxide film 19s is formed on the other side surface. In addition, a mask layer 14S is formed on the upper surface of the channel region 13R.

The stress film 16R has residual stress acting on the side surface of the three-dimensional structure. The residual stress of the stress film 16R causes tensile strain or compression strain to be applied to the side surface of the three-dimensional structure in the in-plane direction of the side surface, thereby generating crystal distortion in the channel region. The crystal distortion makes it possible to improve the carrier mobility in the channel region. When an n-type FET semiconductor device 6 is formed, the stress film 16R is formed such that the tensile strain is generated from the side surface of the three-dimensional structure. When a p-type FET semiconductor device 6 is formed, the stress film 16R is formed such that the compression strain is generated from the side surface of the three-dimensional structure.

As shown in FIGS. 23A and 23B, a gate electrode 10S is continuously formed so as to extend in a direction in which both side surfaces of the three-dimensional structure are opposite to each other. As shown in FIG. 23A, the gate electrode 10S covers the channel region 13R with a gate oxide film 19s interposed therebetween.

As shown in FIG. 23A, the channel regions 13R are formed below the gate electrode 10S. As shown in FIG. 23B, a source electrode 13Ss is formed on one side of the gate electrode 10S in the channel direction, and a drain electrode 13Ds is formed on the other side of the gate electrode 10S in the channel direction. The channel region 13R, the source electrode 13Ss, and the drain electrode 13Ds form the three-dimensional structure. As shown in FIG. 23B, the stress film 16R extends to the side surface of the source electrode 13Ss and the side surface of the drain electrode 13Ds of the three-dimensional structure (fin). Therefore, the stress film 16R is formed in the entire region in which the carriers can be moved such that crystal distortion occurs in the three-dimensional structure. The stress film 16R may be made of the same material as that forming the stress film 16Ua according to the first embodiment under the same deposition conditions as those in the first embodiment.

Then, the insulating film 22R that covers the element structure is formed. A contact plug 25 is provided in a through hole formed in the insulating film 22R so as to reach the gate electrode 10S. In addition, as shown in FIG. 23B, a contact plug 24S connected to the source electrode 13Ss and a contact plug 24D connected to the drain electrode 13Ds are provided in the insulating film 22R.

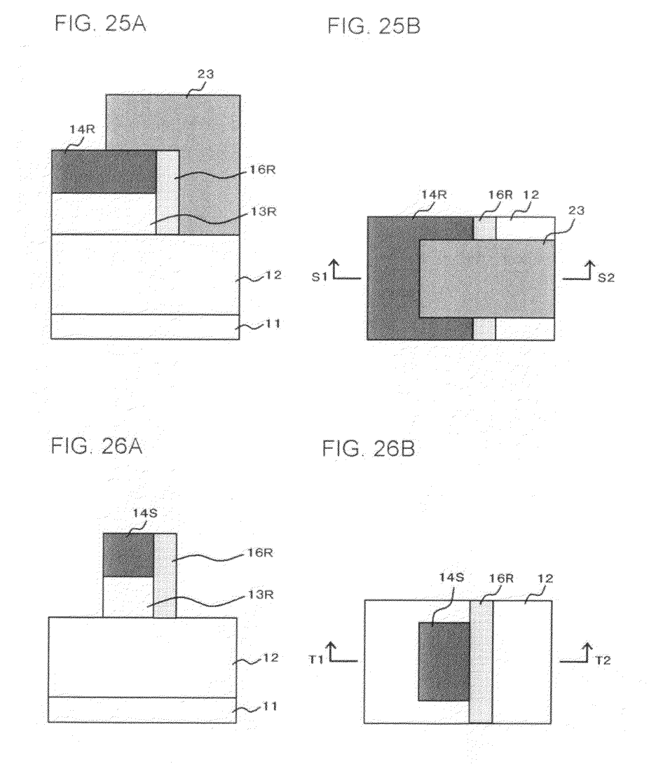

Next, a preferred method of manufacturing the semiconductor device 6 having the above-mentioned structure will be described. FIGS. 24A to 26B are diagrams schematically illustrating a process of manufacturing the semiconductor device 6 having an n-type FET or a p-type FET. FIG. 25A is a cross-sectional view illustrating the structure shown in the top view of FIG. 25B taken along the line S1-S2, and FIG. 26A is a cross-sectional view illustrating the structure shown in the top view of FIG. 26B taken along the line T1-T2.

First, similar to the manufacturing process according to the first embodiment, an SOI substrate (FIG. 2A) having a supporting substrate 11 made of a semiconductor material, a buried-oxide film 12, and an SOI layer 13 formed thereon is prepared. Then, similar to the manufacturing process according to the first embodiment, a mask layer 14 with a thickness of about 100 nm is deposited on the SOI layer 13 by the LPCVD method. Then, the mask layer 14 and the SOI layer 13 are etched by a lithography process and a dry etching process to form a step structure. For example, a silicon nitride film is used as the mask layer 14. FIG. 24A is a diagram illustrating a silicon layer (channel region) 13R and a mask layer 14R forming the step structure.

Then, when an n-type FET is formed, a silicon nitride film with a thickness of, for example, 50 nm is conformally formed as the stress film by the LPCVD method. When a p-type FET is formed, a silicon oxide film with a thickness of, for example, 50 nm is conformally formed as the stress film by the LPCVD method. Then, the stress film is vertically etched by a dry etching technique to form a stress film 16R with a thickness of 50 nm on the side surface of the silicon layer 13R, as shown in FIG. 24B.

Then, as shown in FIG. 25A, a patterned resist film 23 is formed so as to cover a region in which the fin will be formed and the stress film 16R. Dry etching with high selectivity is vertically performed on the silicon layer 13R and the mask layer (silicon nitride film) 14R using the resist film 23 as an etching mask. Then, the resist film 23 is peeled off. As a result, as shown in FIG. 26A, the channel region 13R and the fin are formed. The width of the channel region 13R may be, for example, 80 nm.

Alternatively, instead of the silicon nitride film, a silicon oxide film may be used as the mask layer 14R. In this case, when the mask layer 14R and the silicon layer 13R shown in FIG. 25A are etched, the buried-oxide film 12 outside the element region is likely to be etched such that the supporting substrate 11 is exposed. When the thickness of the buried-oxide film 12 is sufficiently increased in order to prevent exposure, it is possible to prevent errors occurring when the source electrode or the drain electrode is shorted to the supporting substrate 11. Oxide films other than the silicon oxide film may be used as the mask layer 14R.

Then, if necessary, an impurity element is implanted into the channel region 13R by an ion implantation technique, and a heat treatment is performed to activate the impurity element. The subsequent manufacturing processes are substantially the same as those in the first embodiment (FIGS. 12A to 13B), and thus a detailed description thereof will not be repeated. Finally, an insulating film 22R having the contact plugs 24S, 24D, and 25 provided therein is formed to manufacture the semiconductor device 6 shown in FIGS. 23A and 23B. The impurities implanted into the channel region 13R, the source electrode 13Ss, and the drain electrode 13Ds are selected according to whether the fin-type FET is an n type or a p type.

The effects of the semiconductor device 6 according to the sixth embodiment and the method of manufacturing the same are as follows.

As described above, in the semiconductor device 6, after the stress film 16R (FIG. 24B) is formed on the side surface of the step structure, the step structure is etched by using a patterned resist film (resist pattern), thereby forming a three-dimensional structure (FIGS. 25A and 25B and FIGS. 26A and 26B). The gate oxide film 19s and the gate electrode 10S are formed on the second side surface of the three-dimensional structure. Therefore, it is possible to form a high-performance fin-type FET with a small number of processes. Since crystal distortion occurs in the channel region 13R due to the stress film 16R, it is possible to improve a drain current.

The method of manufacturing the semiconductor device 6 having an isolated fin has been described above. However, a structure having a pair of fins may be formed by the manufacturing method according to this embodiment (pair formation). That is, when the SOI layer 13 and the mask layer 14 are etched by using the patterned resist film, a groove may be formed, and fins may be formed in two step structures forming the groove.

### Seventh Embodiment

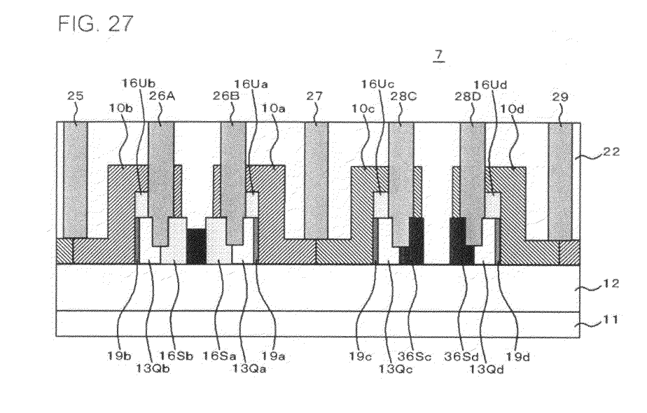

Next, a seventh embodiment of the invention will be described. FIG. 27 is a cross-sectional view illustrating a portion of the structure of a semiconductor device 7 according to the seventh embodiment. Hereinafter, a manufacturing method of integrating the p-type fin FET and the n-type fin FET on the same substrate will be described. The manufacturing method can realize a high-performance CMOS with a minute structure. As will be described below, since the fin is formed by a self-aligning method using the stress film as a mask, it is possible to obtain a minute element without being affected by the limitation of masking in the lithography technique.

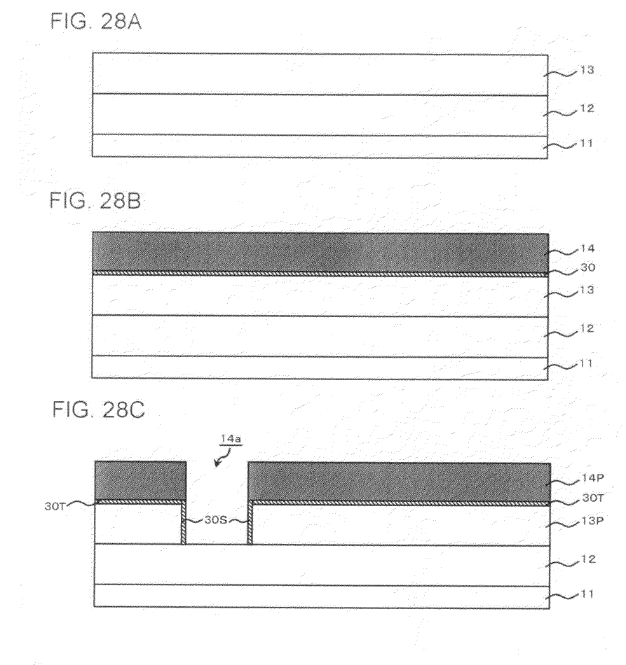

FIGS. 28A to 32B are diagrams schematically illustrating a process of manufacturing the semiconductor device 7.

First, as shown in FIG. 28A, an SOI substrate having a supporting substrate 11 made of a semiconductor material, a buried-oxide film 12, and an SOI layer 13 formed thereon is prepared. The thickness of the buried-oxide film 12 may be, for example, 500 nm, and the thickness of the SOI layer 13 may be, for example, 200 nm.

Then, as shown in FIG. 28B, a mask surface oxide film 30, which is a silicon oxide film, is formed on the upper surface of the SOI layer 13 by thermal oxidation, and a mask layer 14, which is a silicon nitride film, is deposited on the mask surface oxide film 30 by the LPCVD method. The thickness of the mask surface oxide film 30 may be, for example, 2 nm and the thickness of the mask layer 14 may be, for example, 100 nm.

Then, a patterned resist film (not shown) is formed on the mask layer 14 by the lithography technique. The mask layer 14, the mask surface oxide film 30, and the silicon layer 13 are etched in the vertical direction using the resist film as a mask to form a groove, and the resist film peels off. In this case, the width of the groove is, for example, 150 nm. Then, the side surface of the silicon layer 13P exposed by etching is oxidized by a thermal oxidation method to form a mask side surface oxide film 30S (FIG. 28C), which is a silicon oxide film with a thickness of, for example, about 2 nm. In this case, only silicon is selectively oxidized, and no oxide film is formed on the nitride film. As a result, as shown in FIG. 28C, a structure having a groove 14a formed therein is obtained. The p-type FETs are formed on the two step structures forming the groove 14a, respectively, which will be described below.

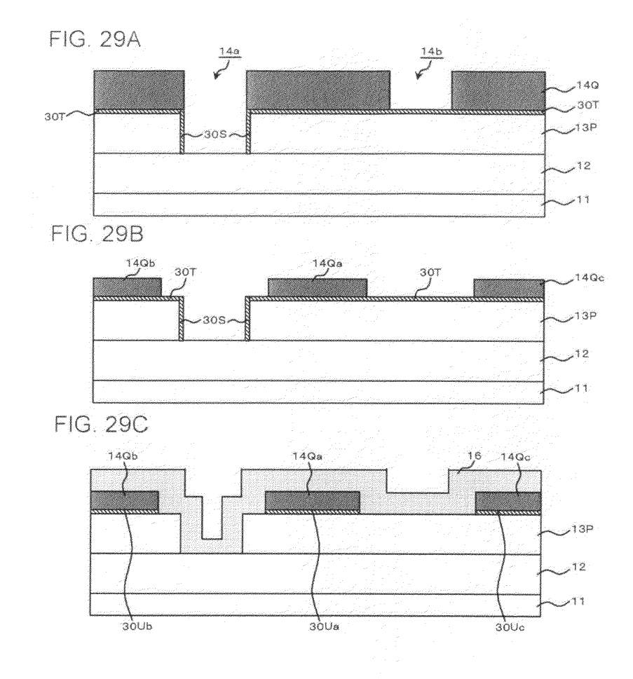

Then, a patterned resist film (not shown) is formed on the mask layer 14 by the lithography technique. The mask layer 14P shown in FIG. 28C is etched in the vertical direction using the resist film as a mask, and then the resist film peels off. As a result, a mask layer 14Q having a groove 14b shown in FIG. 29A is formed. An n-type FET is formed in the vicinity of the groove 14b, which will be described below.

Then, the mask layer 14Q is processed with a phosphoric acid and is then isotropically etched by, for example, 20 nm (FIG. 29B). In this case, since etching starts from the side surface of the groove formed in the mask layer 14Q, the mask layer 14Q on the silicon layer 13P is recessed 20 nm in width. During the phosphoric acid process, since the silicon layer 13P is protected by the mask surface oxide film 30T and the mask side surface oxide film 30S, the silicon layer 13P is not etched. As a result, as shown in FIG. 29B, the etched mask layers 14Qa, 14Qb, and 14Qc are formed.

Then, as shown in FIG. 29C, a stress film 16, which is a silicon oxide film, is conformally formed by the LPCVD method at a high temperature. The thickness of the stress film 16 may be, for example, 50 nm.

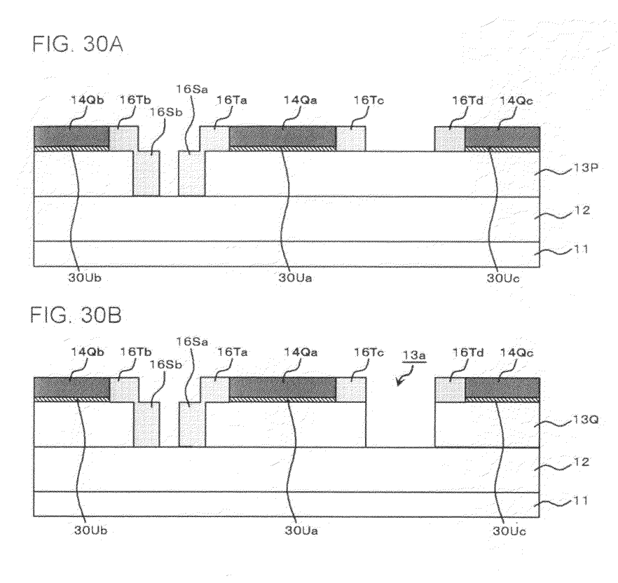

Then, dry etching is performed on the first stress film 16 in the vertical direction. As a result, as shown in FIG. 30A, stress films 16Sa and 16Sb and stress films 16Ta and 16Tb are formed on the side surface and the upper surface of the step structure to be a fin forming the p-type FET, respectively. The stress films 16Sa and 16Sb formed on the side surface serve as a protective mask when the fin is formed by self-alignment in the subsequent process.

Then, dry etching is selectively performed in the vertical direction on the silicon layer 13P using the mask layers 14Qa and 14Qc and stress films 16Tc and 16Td shown in FIG. 30A as an etching mask. As a result, as shown in FIG. 30B, a silicon layer 13Q having a groove 13a that reaches the oxide film 12 is formed.

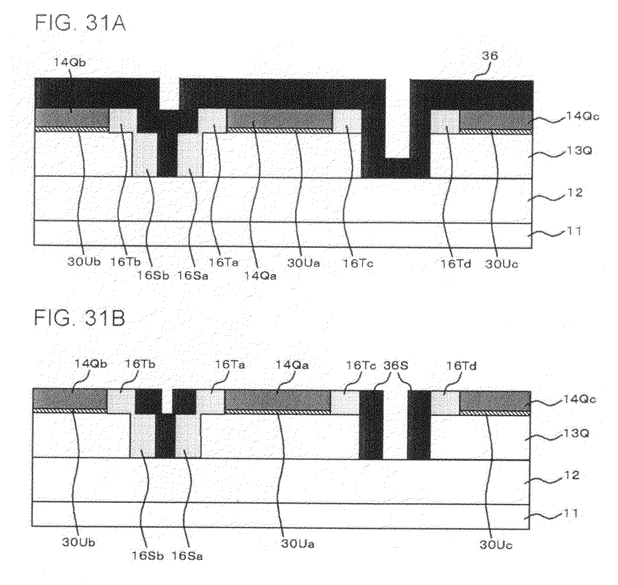

Then, as shown in FIG. 31A, a second stress film 36, which is a silicon nitride film, is conformally formed on the structure shown in FIG. 30B by the LPCVD method at a high temperature. The thickness of the stress film 36 may be, for example, 50 nm.

Then, as shown in FIG. 31B, dry etching is performed on the stress film 36 in the vertical direction. As a result, a stress film 36S is formed on the side surface of the step structure to be a fin forming the n-type FET.

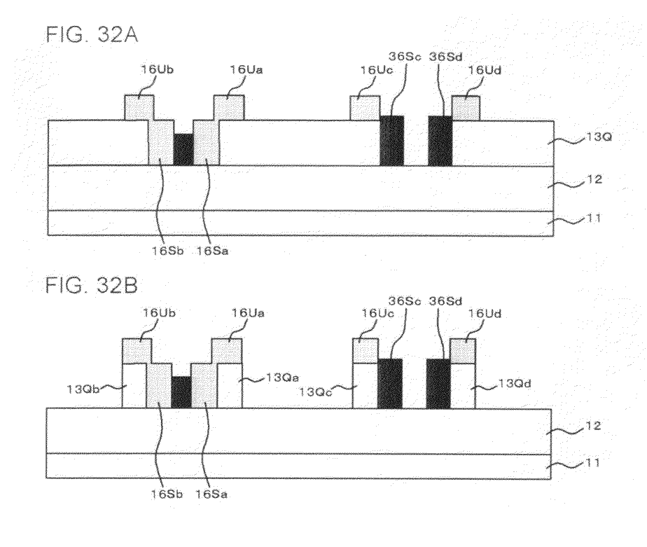

Then, similar to the manufacturing process according to the first embodiment, a patterned resist film (not shown) is formed in an element region by the lithography technique. Then, similar to the manufacturing process according to the first embodiment, dry etching is performed on stress films 16Ta, 16Tb, 16Tc, 16Td, and 36S, the mask layers 14Qa, 14Qb, and 14Qc, and mask surface oxide films 30Ua, 30Ub, and 30Uc outside the element region to expose a silicon layer 13Q. Then, the resist film peels off. In addition, dry etching is selectively performed in the vertical direction on the mask layers 14Qa, 14Qb, and 14Qc (silicon nitride films) and the mask surface oxide films 30Ua, 30Ub, and 30Uc in the element region. As a result, as shown in FIG. 32A, stress films 36Sc and 36Sd remain on the side surface of the step structure to be a fin forming the n-type FET. In addition, the stress films 16Sa and 16Sb remain on the side surface of the step structure to be a fin forming the p-type FET, and stress films 16Ua and 16Ub remain on the upper surface of the step structure.

Then, dry etching is selectively performed on the silicon layer 13Q in the vertical direction using the stress films 16Ua, 16Ub, 36Sc, and 36Sd (silicon oxide films) as an etching mask to form a pair of channel regions 13Qa and 13Qb forming the p-type FET and a pair of channel regions 13Qc and 13Qd forming the n-type FET, as shown in FIG. 32B.

The subsequent manufacturing processes are the same as those in the first embodiment or the second embodiment, and thus a detailed description thereof will not be repeated. As shown in FIG. 27, in the p-type FET, gate oxide films 19a and 19b are formed on the side surfaces of the channel regions 13Qa and 13Qb, respectively. Gate electrodes 10a and 10b are formed so as to respectively cover the gate oxide films 19a and 19b. In the n-type FET, gate oxide films 19c and 19d are formed on the side surfaces of the channel regions 13Qc and 13Qd, respectively. Gate electrodes 10c and 10d are formed so as to respectively cover the gate oxide films 19c and 19d. Then, an insulating film 22 is formed, and contact plugs 25, 26A, 26B, 27, 28C, 28D are provided in the insulating film 22.

In the three-dimensional structure forming the p-type fin FET and the three-dimensional structure forming the n-type fin FET, different impurities are implanted into the fin channel, the gate electrode, and the source/drain electrodes. Therefore, a method may be used which individually and selectively implants ions into an n-type region and a p-type region by a lithography technique using a resist film (not shown) as a mask.

According to the manufacturing method of the seventh embodiment, it is possible to integrate a p-type fin FET and an n-type fin FET on the same substrate. It is possible to apply crystal distortion to the channel regions of the p-type fin FET and the n-type fin FET in the optimal direction. Therefore, it is possible to achieve a CMOS including a fin-type FET with improved carrier (hole and electron) mobility. In addition, it is possible to achieve a minute CMOS structure by forming a fin channel using a self-aligning method, without depending on the masking accuracy of the lithography technique.

In this embodiment, fins of the n-type FET and the p-type FET are formed in pair. However, the fins of the n-type FET and the p-type FET may be formed in an isolated manner.

The exemplary embodiments of the invention have been described above with reference to the accompanying drawings.

The structures of the semiconductor devices 1 to 7 according to the above-described embodiments are all so-called mono-gate structures in which a gate electrode is formed on the side surface and the upper surface of a fin (three-dimensional structure) with a gate oxide film interposed therebetween. Other structures include a double gate structure or a tri-gate structure in which a gate electrode is formed on two surfaces (two side surfaces) or three surfaces (two side surfaces and the upper surface) of a fin with a gate oxide film interposed therebetween, and a structure (gate-all-around structure) in which a gate electrode is formed on the entire circumferential surface of a pillar-shaped three-dimensional structure. In these structures, the width W of an element, which is the width of a region in which a current flows, is more effectively increased to improve the amount of drain current, as compared to the mono-gate structure. However, in a nano-region in which the width of the fin is equal to or less than 20 nm, a difference in the effective width W is cancelled due to the influence of the quantum of an inversion layer, so that electrical characteristics of the above-mentioned structure may be substantially the same as those of the mono-gate structure. In a minute element structure, it is important to improve the carrier transmission characteristics in order to improve the driving capability of an element. Therefore, the structure according to the invention that actively uses the crystal distortion technique is effective in improving the performance of a minute element in the nano-region.

When a silicon crystal is used, representative examples of the crystal orientation of a fin channel surface include, for example, a (100) plane, a (110) plane, and a (111) plane. In addition, examples of the crystal orientation in the direction in which a channel current flows includes a <100> direction, a <110> direction, and a <111> direction. However, the invention is not limited to these crystal orientations.

The above-described embodiments of the invention are just illustrative, and the invention may include various other structures. For example, in the above-described embodiments, the three-dimensional structure including the channel region has a fin shape that protrudes upward from the upper surface of the supporting substrate, but the invention is not limited thereto. Instead of the fin-shaped three-dimensional structure, a three-dimensional structure made of a crystal having a cylindrical pillar shape or a nano-sized wire shape may be used.

In the semiconductor devices 1 to 7 according to the above-described embodiments, the width of the fin-shaped three-dimensional structure is not particularly limited, but is preferably equal to or less than about 20 nm. Since the width of the channel region of the three-dimensional structure is small, it is possible to reduce the sizes of the semiconductor devices 1 to 7 and thus strengthen distortion applied from the stress film to a crystal in the channel region.

In the semiconductor devices 1 to 7 according to the above-described embodiments, the SOI substrate is used for ease of element separation, but the invention is not limited thereto. Instead of the SOI substrate, a semiconductor substrate may be used. In this case, it is possible to obtain substantially the same effects as those in the above-described embodiments.

In the semiconductor devices 1 to 7 according to the above-described embodiments, the source electrodes 13Sa, 13Sb, 13Sr, and 13Ss and the drain electrodes 13Da, 13Db, 13Dr, and 13Ds are obtained by forming a pn junction in the three-dimensional structure (fin) using an ion implantation technique, but the invention is not limited thereto. For example, a Schottky barrier junction may be formed in the three-dimensional structure (fin) to form the source electrodes 13Sa, 13Sb, 13Sr, and 13Ss and the drain electrodes 13Da, 13Db, 13Dr, and 13Ds.

It is apparent that the present invention is not limited to the above embodiment, but may be modified and changed without departing from the scope and spirit of the invention.

What is claimed is:

1. A semiconductor device comprising:
a substrate;
a three-dimensional structure that is formed over a main surface of said substrate, includes first and second side surfaces opposite to each other in a direction intersecting a channel direction which is parallel to the in-plane direction of said substrate, and extends in said channel direction;
a stress film that is formed over said first side surface and includes a residual stress acting on said first side surface;
a gate insulating film that is formed over said second side surface; and
a gate electrode that covers at least said second side surface of said three-dimensional structure with said gate insulating film interposed between said three-dimensional structure and said gate electrode and extends in a direction in which said first and second side surfaces are opposite to each other,
wherein said three-dimensional structure includes a source electrode and a drain electrode on both sides of said gate electrode in said channel direction and includes a channel region between said source electrode and said drain electrode.

2. The semiconductor device as set forth in claim 1,
wherein said stress film extends to the side surface of said source electrode and the side surface of said drain electrode.

3. The semiconductor device as set forth in claim 1,
wherein said stress film extends to an upper surface of said source electrode and an upper surface of said drain electrode.

4. The semiconductor device as set forth in claim 1,
wherein the residual stress of said stress film causes a tensile strain to be applied to said first side surface in the in-plane direction of said first side surface.

5. The semiconductor device as set forth in claim 1,
wherein the residual stress of said stress film causes a compression strain to be applied to said first side surface in the in-plane direction of said first side surface.

6. The semiconductor device as set forth in claim 1,
wherein said stress film is an insulating film including at least one of a silicon nitride film and a silicon oxide film.

7. The semiconductor device as set forth in claim 1, further comprising:
an upper stress film that is formed over the upper surface of said three-dimensional structure,
wherein said upper stress film includes a residual stress acting on the upper surface of said three-dimensional structure.

8. The semiconductor device as set forth in claim 7,
wherein the residual stress of said upper stress film causes a tensile strain to be applied to said upper surface in the in-plane direction of said upper surface.

9. The semiconductor device as set forth in claim 7,
wherein the residual stress of said upper stress film causes a compression strain to be applied to said upper surface in the in-plane direction of said upper surface.

10. The semiconductor device as set forth in claim 7,
wherein said upper stress film is an insulating film including at least one of a silicon nitride film and a silicon oxide film.

11. The semiconductor device as set forth in claim 1,
wherein said substrate includes a supporting substrate and an oxide film formed over said supporting substrate, and
said three-dimensional structure is formed over said oxide film.

12. A method of manufacturing a semiconductor device, comprising:
etching a semiconductor layer formed over a substrate to form a step structure including a first side surface;
forming a patterned stress film over an upper surface and said first side surface of said step structure;
performing etching on said step structure using said stress film as an etching mask to form a second side surface opposite to said first side surface, thereby forming a three-dimensional structure that includes said first and second side surfaces and extends in a channel direction parallel to the in-plane direction of said substrate;
forming a gate insulating film over said second side surface; and
forming a gate electrode that covers at least said second side surface of said three-dimensional structure with said gate insulating film interposed between said three-dimensional structure and said gate electrode and extends in a direction in which said first and second side surfaces are opposite to each other,
wherein said stress film includes a residual stress acting on said first side surface, and
said three-dimensional structure includes a source electrode and a drain electrode on both sides of said gate electrode in said channel direction and includes a channel region between said source electrode and said drain electrode.

13. The method of manufacturing a semiconductor device as set forth in claim 12,
wherein said stress film extends to the side surface of said source electrode and the side surface of said drain electrode.

14. The method of manufacturing a semiconductor device as set forth in claim 12,
wherein said stress film extends to an upper surface of said source electrode and an upper surface of said drain electrode.

15. The method of manufacturing a semiconductor device as set forth in claim 12,
wherein the residual stress of said stress film causes a tensile strain to be applied to said first side surface in the in-plane direction of said first side surface.

16. The method of manufacturing a semiconductor device as set forth in claim 12,
wherein the residual stress of said stress film causes a compression strain to be applied to said first side surface in the in-plane direction of said first side surface.

17. The method of manufacturing a semiconductor device as set forth in claim 12,
wherein said stress film is an insulating film including at least one of a silicon nitride film and a silicon oxide film.

18. The method of manufacturing a semiconductor device as set forth in claim 12,
wherein said step of forming said step structure includes:
forming a film, which will form said stress film, over said substrate;
forming a patterned mask layer over said film;
performing etching to said film using said mask layer as an etching mask to form said step structure; and
removing a portion of said mask layer in the vicinity of said first side surface by etching to expose a portion of the upper surface of said step structure.

19. The method of manufacturing a semiconductor device as set forth in claim 12,
wherein said step of forming said step structure includes:
forming a first protective film over said substrate;
forming a film, which will form said stress film, over said first protective film;
forming a patterned mask layer over said film; and
performing etching to said film using said mask layer as an etching mask to form said step structure, and
said step of forming said stress film includes:
after said step of forming said step structure, forming a second protective film over said first side surface;
performing etching on said mask layer using said first and second protective films as an etching mask to expose a portion of the upper surface of said first protective film; and
removing the exposed portion of said first protective film and said second protective film to expose said first side surface and a portion of the upper surface of said step structure.

20. The method of manufacturing a semiconductor device as set forth in claim 12,
wherein said step of forming said structure includes:
etching said semiconductor layer to form a groove, thereby forming a step structure including said first side surface and a step structure including a third side surface at the same time,
said step of forming said stress film includes:
forming said stress film as a first stress film and forming a second patterned stress film on the upper surface and said third side surface of said step structure including said third side surface,
said step of forming said three-dimensional structure includes:
performing etching on said step structure including said first side surface and said step structure including said third side surface using said first and second stress films as an etching mask to form said second side surface and a fourth side surface opposite to said third side surface, thereby simultaneously forming a three-dimensional structure including said first and second side surfaces and a three-dimensional structure that includes said third and fourth side surfaces and extends in said channel direction,
said step of forming said gate insulating film includes:
forming said gate insulating film as a first gate insulating film over said second side surface and forming a second gate insulating film over said fourth side surface,
said gate electrode extends so as to cover said fourth side surface with said second gate insulating film interposed between said three-dimensional structure and said gate electrode,
said second stress film includes a residual stress acting on said third side surface, and
said three-dimensional structure including said third and fourth side surfaces includes a source electrode and a drain electrode on both sides of said second gate electrode in said channel direction and includes a channel region between said source electrode and said drain electrode.

21. The method of manufacturing a semiconductor device as set forth in claim 12,
wherein said substrate includes a supporting substrate, a buried-oxide film that is formed over said supporting substrate, and said semiconductor layer that is formed over said buried-oxide film.

22. A method of manufacturing a semiconductor device, comprising:
forming a patterned mask layer over a semiconductor layer formed over a substrate;
performing etching on said semiconductor layer using said mask layer as an etching mask to form a step structure including a first side surface;
forming a stress film over said first side surface;
forming a patterned resist film so as to cover said first side surface;
performing etching on a laminate of said step structure and said mask layer using said resist film as an etching mask to form a second side surface opposite to said first side surface, thereby forming a three-dimensional structure that includes said first and second side surfaces and extends in a channel direction parallel to the in-plane direction of said substrate;
forming a gate insulating film over said second side surface; and
forming a gate electrode that covers at least said second side surface of said three-dimensional structure with said gate insulating film interposed between said three-dimensional structure and said gate electrode and extends in a direction in which said first and second side surfaces are opposite to each other,
wherein said stress film includes a residual stress acting on said first side surface, and
said three-dimensional structure includes a source electrode and a drain electrode on both sides of said gate electrode in said channel direction and includes a channel region between said source electrode and said drain electrode.
